(19) United States
(12) Patent Application Publication
(10) Pub. No.: US 2014/0034119 A1
(43) Pub. Date: Feb. 6, 2014

(54) PHOTOELECTRIC DEVICE

(71) Applicant: SAMSUNG SDI CO., LTD., Yongin-si (KR)

(72) Inventors: Cho-Young Lee, Yongin-si (KR); Min-Seok Oh, Yongin-si (KR); Nam-Kyu Song, Yongin-si (KR); Yu-Kyung Kim, Yongin-si (KR); Yun-Seok Lee, Yongin-si (KR)

(73) Assignee: SAMSUNG SDI CO., LTD., Yongin-si (KR)

(21) Appl. No.: 13/727,549

(22) Filed: Dec. 26, 2012

(30) Foreign Application Priority Data
Aug. 2, 2012 (KR) 10-2012-0084986

(51) Int. Cl. H01L 31/076

(52) U.S. Cl. CPC H01L 31/076
USPC 136/255

(57) ABSTRACT

A photoelectric device that reduces optical loss, reduces recombination loss of carriers, and can be manufactured by using a simplified process is provided. The photoelectric device includes a semiconductor substrate, a first semiconductor stack on a first surface of the semiconductor substrate and having a first conductivity, and a second semiconductor stack on the first surface of the semiconductor substrate and having a second conductivity opposite to the first conductivity. Edge portions of the first and second semiconductor stacks face each other with an insulating portion therebetween.

### CROSS-REFERENCE TO RELATED APPLICATION

This application claims priority to and the benefit of Korean Patent Application No. 10-2012-0084986, filed on Aug. 2, 2012 in the Korean Intellectual Property Office, the entire content of which is incorporated herein by reference.

### BACKGROUND

1. Field

Aspects of embodiments of the present invention relate to photoelectric devices.

2. Description of the Related Art

Recently, due to the increased demand for finite energy sources (such as fossil fuels) and to the worsening global environmental problems, the development of clean energy has accelerated. As a clean energy, solar power generation that uses solar energy is expected to be a widely used energy source since solar energy may be directly converted to electricity.

However, the cost of power generation from an industrial solar cell remains higher than that of fossil fuel power generation. An increase in efficiency of the solar power generation would allow more widespread application of the solar cell. Possible ways of increasing this efficiency include reducing optical loss, reducing recombination loss, and reducing series resistance with respect to an optical current generated in the solar cell. Another way of saving costs is to develop a new structure in which manufacturing costs and process simplification are considered for mass production of high efficiency solar cells.

### SUMMARY

One or more embodiments of the present invention provide for photoelectric devices that can reduce optical loss, reduce recombination loss of carriers, and have a simplified manufacturing process. Additional aspects will be set forth in part in the description that follows and, in part, will be apparent from the description, or may be learned by practice of the presented embodiments.

According to an exemplary embodiment of the present invention, a photoelectric device is provided. The photoelectric device includes a semiconductor substrate, a first semiconductor stack on a first surface of the semiconductor substrate and having a first conductivity, and a second semiconductor stack on the first surface of the semiconductor substrate and having a second conductivity opposite to the first conductivity. Edge portions of the first and second semiconductor stacks face each other with an insulating portion therebetween.

The first semiconductor stack may constitute a base for collecting major carriers and the second semiconductor stack may constitute an emitter for collecting minor carriers.

The edge portion of the first semiconductor stack, the insulating portion, and the edge portion of the second semiconductor stack may be stacked sequentially from the semiconductor substrate.

The edge portions of the first and second semiconductor stacks may be vertically separated from each other by a first height.

The edge portion of the second semiconductor stack may be supported on the insulation portion. An edge surface of the second semiconductor stack and an edge surface of the insulating portion may be aligned with each other.

The edge portion of the first semiconductor stack may extend on the semiconductor substrate in a first direction parallel to the semiconductor substrate.

The edge portion of the second semiconductor stack may be vertically separated by a second height from a main body portion of the second semiconductor stack that extends in a first direction parallel to the semiconductor substrate.

The second semiconductor stack may further include a connection portion that extends in a second direction different from the first direction to connect the main body portion and the edge portion.

The connection portion of the second semiconductor stack may extend in the second direction to cover an edge surface of the first semiconductor stack and the edge surface of the insulating portion.

The connection portion of the second semiconductor stack may contact the edge surface of the first semiconductor stack.

The first semiconductor stack may include a first intrinsic semiconductor layer and a first conductive semiconductor layer that extend in the first direction on the semiconductor substrate. The connection portion of the second semiconductor stack may include a second intrinsic semiconductor layer and a second conductive semiconductor layer that extend parallel to each other in the second direction.

The second intrinsic semiconductor layer may contact an edge surface of the first intrinsic semiconductor layer.

The second intrinsic semiconductor layer may contact the first intrinsic semiconductor layer along a thickness direction of the first intrinsic semiconductor layer. The first intrinsic semiconductor layer may have a thickness smaller than that of the first conductive semiconductor layer.

The second intrinsic semiconductor layer may contact an edge surface of the first conductive semiconductor layer.

The second intrinsic semiconductor layer may constitute an emitter having a band gap narrower than that of the first intrinsic semiconductor layer constituting a base.

The insulating portion may include a silicon nitride film.

The first semiconductor stack may include a first intrinsic semiconductor layer and a first conductive semiconductor layer stacked on the semiconductor substrate. The second semiconductor stack may include a second intrinsic semiconductor layer and a second conductive semiconductor layer.

The photoelectric device may further include first and second transparent conductive films respectively on the first and second conductive semiconductor layers.

The photoelectric device may further include first and second metal films respectively on the first and second transparent conductive films.

### BRIEF DESCRIPTION OF THE DRAWINGS

These and/or other aspects will become apparent and more readily appreciated from the following description of exemplary embodiments, taken in conjunction with the accompanying drawings of which:

FIG. 1 is a cross-sectional view of a photoelectric device according to an embodiment of the present invention;

FIG. 2 is an enlarged cross-sectional view of an overlapping region of first and second semiconductor stacks according to an embodiment of the present invention;

FIG. 3 is an energy band diagram for illustrating a principle of reducing a recombination loss caused by contact between the first and second semiconductor stacks;

FIG. 4 is a cross-sectional view of a photoelectric device according to a comparative example 1 to compare with an embodiment of the present invention;

FIG. 5 is a cross-sectional view of a photoelectric device according to a comparative example 2 to compare with an embodiment of the present invention; and

FIGS. 6A through 6S are cross-sectional views showing a method of manufacturing a photoelectric device according to an embodiment of the present invention.

### DETAILED DESCRIPTION

The present invention will now be described more fully with reference to the accompanying drawings, in which exemplary embodiments of the invention are shown.

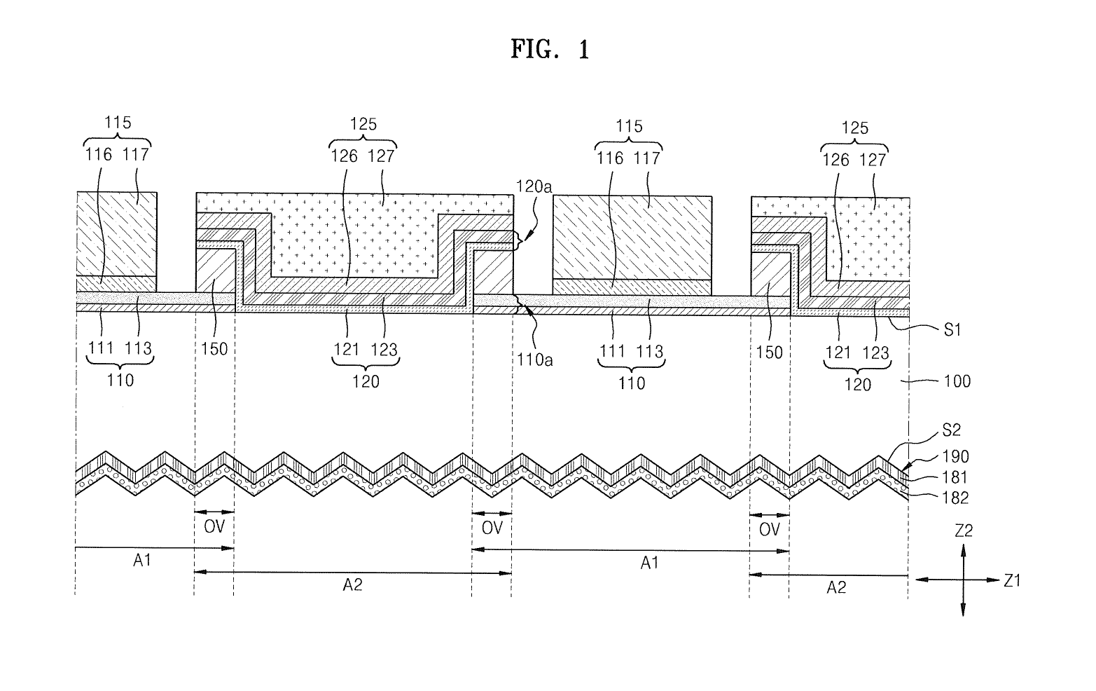

FIG. 1 is a cross-sectional view of a photoelectric device according to an embodiment of the present invention.

Referring to FIG. 1, the photoelectric device includes a semiconductor substrate 100, a first conductive type (for example, n-type) first semiconductor stack 110 and a second conductive type (for example, p-type) second semiconductor stack 120, which are formed on the semiconductor substrate 100, and first and second electrodes 115 and 125 electrically connected to the first and second semiconductor stacks 110 and 120. For example, a plurality of the first and second semiconductor stacks 110 and 120 may be formed and alternately arranged on the semiconductor substrate 100.

The semiconductor substrate 100 has a first surface S1 and a second surface S2 opposite to the first surface S1. A base electrode (such as the first electrode 115) and an emitter electrode (such as the second electrode 125) are formed on the first surface S1. Accordingly, the second surface S2 (from which an electrode structure has been removed) functions as a light receiving surface. Thus, effective incident light may be increased and optical loss may be reduced. That is, by not forming electrodes on the light receiving surface S2, optical loss caused by the electrodes may be reduced and a high output may be obtained when compared to a solar cell in which electrodes are formed on the light receiving surface S2.

When the semiconductor substrate 100 receives light through the second surface S2, the semiconductor substrate 100 generates optical generation carriers (hereinafter, carriers). The carriers include holes and electrons from the semiconductor substrate 100. The semiconductor substrate 100 may be, for example, a monocrystalline silicon substrate or a polycrystalline silicon substrate having an n-type or a p-type conductivity. For example, the semiconductor substrate 100 may be an n-type monocrystalline silicon substrate. For ease of description, the semiconductor substrate 100 of the exemplary embodiment of FIG. 1 is described in reference to an n-type monocrystalline silicon substrate.

In the exemplary embodiment of claim 1, a texture structure 190 having a corrugated pattern is formed on the second surface S2 of the semiconductor substrate 100. The texture structure 190 reduces a reflection rate of incident light, and has a corrugated surface that includes a plurality of fine protrusions. A passivation film 181 is formed on the second surface S2 of the semiconductor substrate 100. The passivation film 181 reduces or prevents recombination of the carriers generated in the semiconductor substrate 100, which may lead to increased carrier collection efficiency.

The passivation film 181 may be formed, for example, of a material doped with a dopant that has the same conductivity as the semiconductor substrate 100. For example, the passivation film 181 may be a highly doped n+ layer formed on the second surface S2 of the semiconductor substrate 100. The passivation film 181 may form a front surface field (FSF) for reducing the surface recombination loss. The passivation film 181 may be formed, for example, of a silicon oxide (SiOx) film or a silicon nitride (SiNx) film.

A reflection prevention film 182 is formed on the passivation film 181. The reflection prevention film 182 is formed on the second surface S2, which is the light receiving surface S2. The reflection prevention film 182 may increase optical absorption of the semiconductor substrate 100 by reducing reflection of incident light, which may lead to increased optical collection efficiency. The reflection prevention film 182 may be formed, for example, of a silicon oxide film or a silicon nitride film. For example, the reflection prevention film 182 may be a monolayer of a silicon oxide (SiOx) film or a silicon nitride (SiNx) film, or may be a composite layer of a silicon oxide (SiOx) film and a silicon nitride (SiNx) film, which have refractive indexes that are different from each other.

In the exemplary embodiment of FIG. 1, the passivation film 181 and the reflection prevention film 182 are formed as separated layers. In other embodiments, the passivation film 181 and the reflection prevention film 182 may be formed as a single layer structure.

Returning to the exemplary embodiment of FIG. 1, first and second semiconductor stacks 110 and 120 having opposite conductivities are formed on the first surface Si of the semiconductor substrate 100. Further, a plurality of first and second semiconductor stacks 110 and 120 may be alternately arranged along the first surface S1 of the semiconductor substrate 100. The first and second semiconductor stacks 110 and 120 may respectively form a base and emitter that separately collect carriers (electrons and holes) generated from the semiconductor substrate 100. The first and second semiconductor stacks 110 and 120 are respectively formed in (partially overlapping) first and second semiconductor regions A1 and A2 on the first surface S1 of the semiconductor substrate 100.

The first semiconductor stack 110 includes a first intrinsic semiconductor layer 111 and a first conductive semiconductor layer 113, which are sequentially stacked on the semiconductor substrate 100. The first intrinsic semiconductor layer 111 and the first conductive semiconductor layer 113 may be formed, for example, of amorphous silicon a-Si or fine crystal silicon μc-Si. For example, the first intrinsic semiconductor layer 111 and the first conductive semiconductor layer 113 may be formed of hydrogenated amorphous silicon a-Si:H. For ease of description, the first intrinsic semiconductor layer 111 and the first conductive semiconductor layer 113 of the exemplary embodiment of FIG. 1 are described as being formed of hydrogenated amorphous silicon a-Si:H.

The first intrinsic semiconductor layer 111 may be formed, for example, without adding a dopant or by adding a minor amount of a dopant. The first intrinsic semiconductor layer 111 may passivate the first surface S1 of the semiconductor substrate 100 to reduce or prevent recombination of carriers generated in the semiconductor substrate 100. Further, the first intrinsic semiconductor layer 111 may increase an interface characteristic between the semiconductor substrate 100 formed of crystalline silicon and the first conductive semiconductor layer 113 formed of amorphous silicon.

The first conductive semiconductor layer 113 may be formed, for example, by adding an n-type or a p-type dopant. For example, the first conductive semiconductor layer 113 may be doped with an n-type dopant, which is the same conductivity as the semiconductor substrate 100. In addition, the first conductive semiconductor layer 113 may form a base that collects major carriers (electrons) from the n-type semiconductor substrate 100.

A first electrode 115 is formed on the first semiconductor stack 110. The first electrode 115 includes a first transparent conductive film 116 that is electrically conductive and optically transparent. For example, the first transparent conductive film 116 may be formed of a transparent conducting oxide (TCO) such as indium tin oxide (ITO) or zinc oxide (ZnO). The first electrode 115 further includes a first metal film 117 on the first transparent conductive film 116. The first metal film 117 may include, for example, a metal such as Ag, Al, Cu, or Ni. The first metal film 117 may be formed of a metal having high electrical conductivity to reduce series resistance because the first metal film 117 forms an optical current path. The first transparent conductive film 116 and the first metal film 117 are sequentially stacked on the first semiconductor stack 110. Accordingly, the first transparent conductive film 116 may intermediate an electrical connection (for example, reduce contact resistance) between the first semiconductor stack 110 and the first metal film 117.

The second semiconductor stack 120 includes a second intrinsic semiconductor layer 121 and a second conductive semiconductor layer 123, which are sequentially stacked on the semiconductor substrate 100. The second intrinsic semiconductor layer 121 and the second conductive semiconductor layer 123 may be formed, for example, of amorphous silicon a-Si or fine crystalline silicon μc-Si. For example, the second intrinsic semiconductor layer 121 and the second conductive semiconductor layer 123 may be formed of hydrogenated amorphous silicon a-Si:H. For ease of description, the second intrinsic semiconductor layer 121 and the second conductive semiconductor layer 123 of the exemplary embodiment of FIG. 1 are described as being formed of hydrogenated amorphous silicon a-Si:H.

The second intrinsic semiconductor layer 121 may be formed, for example, without adding a dopant or by adding a small amount of a dopant. The second intrinsic semiconductor layer 121 may passivate the semiconductor substrate 100 to reduce or prevent recombination of carriers generated in the semiconductor substrate 100. Further, the second intrinsic semiconductor layer 121 may increase an interface characteristic between the semiconductor substrate 100 formed of crystalline silicon and the second conductive semiconductor layer 123 formed of amorphous silicon.

The second conductive semiconductor layer 123 may be formed, for example, by adding an n-type or a p-type dopant. For example, the second conductive semiconductor layer 123 may be doped with a p-type dopant, which is opposite in conductivity to that of the semiconductor substrate 100. In addition, the second conductive semiconductor layer 123 may form an emitter that collects minor carriers (holes) from the n-type semiconductor substrate 100.

A second electrode 125 is formed on the second semiconductor stack 120. The second electrode 125 includes a second transparent conductive film 126 that is electrically conductive and optically transparent. For example, the second transparent conductive film 126 may be formed of a TCO such as ITO or ZnO. The second electrode 125 further includes a second metal film 127 formed on the second transparent conductive film 126. The second metal film 127 may include, for example, a metal such as Ag, Al, Cu, or Ni. The second metal film 127 may be formed of a metal having high electrical conductivity to reduce series resistance since the second metal film 127 forms an optical current path. The second transparent conductive film 126 and the second metal film 127 are sequentially stacked on the second semiconductor stack 120. Accordingly, the second transparent conductive film 126 may intermediate the electrical connection (for example, reduce contact resistance) between the second semiconductor stack 120 and the second metal film 127.

The first and second semiconductor stacks 110 and 120 are alternately arranged (for example, adjacent) along the first surface S1 of the semiconductor substrate 100. In addition, edge portions 110a and 120a of the first and second semiconductor stacks 110 and 120 overlap each other, thus forming overlapping regions OV. For example, the overlapping regions OV of the first and second semiconductor stacks 110 and 120 may correspond to regions where a first semiconductor region A1 (which is a projected region of the first semiconductor stack 110 onto the semiconductor substrate 100) and a second semiconductor region A2 (which is a projected region of the second semiconductor stack 120 onto the semiconductor substrate 100) overlap.

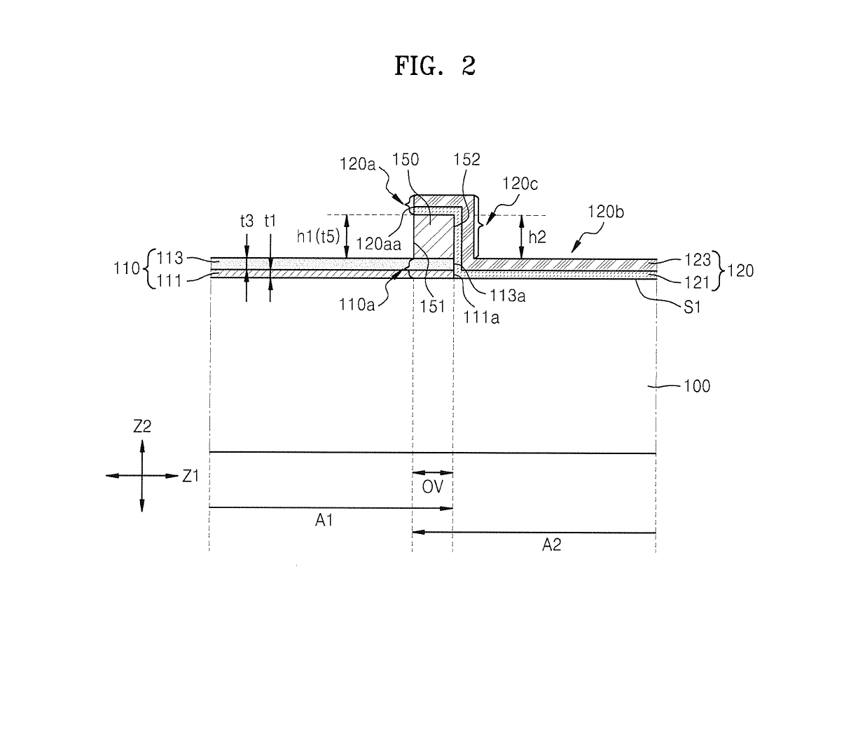

FIG. 2 is an enlarged cross-sectional view of an overlapping region OV of the first and second semiconductor stacks 110 and 120 according to an exemplary embodiment of the present invention. Referring to FIG. 2, the edge portions 110a and 120a of the first and second semiconductor stacks 110 and 120 face each other with an insulating portion (or insulation portion) 150 therebetween.

In the exemplary embodiment of FIG. 2, the edge portion 110a of the first semiconductor stack 110, the insulating portion 150, and the edge portion 120a of the second semiconductor stack 120 are sequentially stacked from the semiconductor substrate 100. The edge portion 120a of the second semiconductor stack 120 is formed at a first height h1 above the first semiconductor stack 110. The edge portions 110a and 120a of the first and second semiconductor stacks 110 and 120 face each other with the insulating portion 150 therebetween. For example, the edge portion 120a of the second semiconductor stack 120 is supported by the insulating portion 150. Accordingly, the first height h1 substantially corresponds to a thickness t5 of the insulating portion 150.

The first semiconductor stack 110 extends in a first direction Z1 parallel to the semiconductor substrate 100 on the semiconductor substrate 100. Further, the edge portion 110a of the first semiconductor stack 110 is formed at an edge of the first semiconductor stack 110 in the extended direction.

The second semiconductor stack 120 includes a main body portion 120b on the semiconductor substrate 100, the edge portion 120a vertically separated by a second height h2 from the main body portion 120b, and a connection portion 120c that connects the main body portion 120b and the edge portion 120a. The main body portion 120b also extends in the first direction Z1 parallel to the semiconductor substrate 100 on the semiconductor substrate 100. In addition, the edge portion 120a is formed at a second height h2 above the main body portion 120b. The connection portion 120c extends in a second direction Z2 that is perpendicular to the semiconductor substrate 100 to connect the main body portion 120b and the edge portion 120a.

The connection portion 120c of the second semiconductor stack 120 contacts the first semiconductor stack 110. As illustrated in the exemplary embodiment of FIG. 2, the connection portion 120c of the second semiconductor stack 120 contacts edge surfaces 111a and 113a of the first semiconductor stack 110. Since the connection portion 120c of the second semiconductor stack 120 contacts the edge surfaces 111a and 113a of the first semiconductor stack 110, the semiconductor substrate 100 is not exposed therebetween. If a portion of the semiconductor substrate 100 is exposed between the first semiconductor stack 110 and the second semiconductor stack 120, surface recombination loss may occur along a surface defect of the exposed semiconductor substrate 100.

The connection portion 120c of the second semiconductor stack 120 includes the second intrinsic semiconductor layer 121 and the second conductive semiconductor layer 123, which are parallel to each other, and contacts the first intrinsic semiconductor layer 111 and the first conductive semiconductor layer 113, which extend in the first direction Z1 on the semiconductor substrate 100. The second intrinsic semiconductor layer 121 contacts the first intrinsic semiconductor layer 111 and the first conductive semiconductor layer 113 by extending in the second direction Z2 to cover the edge surfaces 111a and 113a of the first intrinsic semiconductor layer 111 and the first conductive semiconductor layer 113.

As illustrated in the exemplary embodiment of FIG. 2, the second intrinsic semiconductor layer 121 contacts (and covers) the first intrinsic semiconductor layer 111 along a thickness direction (the second direction Z2) of the first intrinsic semiconductor layer 111. Accordingly, a contact area between the first and second intrinsic semiconductor layers 111 and 121 varies according to the thickness t1 of the first intrinsic semiconductor layer 111. The recombination loss and current leakage of carriers due to the contact between the first intrinsic semiconductor layer 111 and the second intrinsic semiconductor layer 121 may be reduced or minimized by limiting the thickness t1 of the first intrinsic semiconductor layer 111 to an angstrom (Å) scale, for example, less than 50 Å (i.e., less than 5 nm). For example, the first intrinsic semiconductor layer 111 may be formed to have a thickness t1 of less than 50 Å, and the first conductive semiconductor layer 113 may be formed to have a thickness t3 of 10 μm or more. The first intrinsic semiconductor layer 111 is thus formed significantly thinner (for example, over 1000 times thinner) than the first conductive semiconductor layer 113.

When the first and second semiconductor stacks 110 and 120 (having opposite conductivity from each other) contact each other, in a charge separation process in which optical carriers generated in the semiconductor substrate 100 are separately collected in the first and second semiconductor stacks 110 and 120 due to an internal electric field, recombination occurs through a contact between the first and second semiconductor stacks 110 and 120 (that is, between the first intrinsic semiconductor layer 111 and the second intrinsic semiconductor layer 121). Thus, inefficiencies such as a current leakage, recombination loss, and a reduction of carriers may occur. The recombination loss may be reduced or minimized by controlling the thickness t1 of the first intrinsic semiconductor layer 111 (such as making t1 extremely small, e.g., under 50 Å).

Recombination loss may also occur through another contact between the first and second semiconductor stacks 110 and 120, that is, between the second intrinsic semiconductor layer 121 and the first conductive semiconductor layer 113. As shown in FIG. 2, the second intrinsic semiconductor layer 121 contacts the edge portion 110a of the first semiconductor stack 110 including the first intrinsic semiconductor layer 111 (at the edge surface 111a) and the first conductive semiconductor layer 113 (at the edge surface 113a). The edge surface 113a of the first conductive semiconductor layer 113 faces the second conductive semiconductor portion 123 (in the connection portion 120c) with the second intrinsic semiconductor layer 121 interposed therebetween. Therefore, carriers (for example, holes) of the second conductive semiconductor layer 123 or the second intrinsic semiconductor layer 121 may be diffused into the first conductive semiconductor layer 113 that has the first conductivity opposite to the second conductivity, and may be dissipated by recombination.

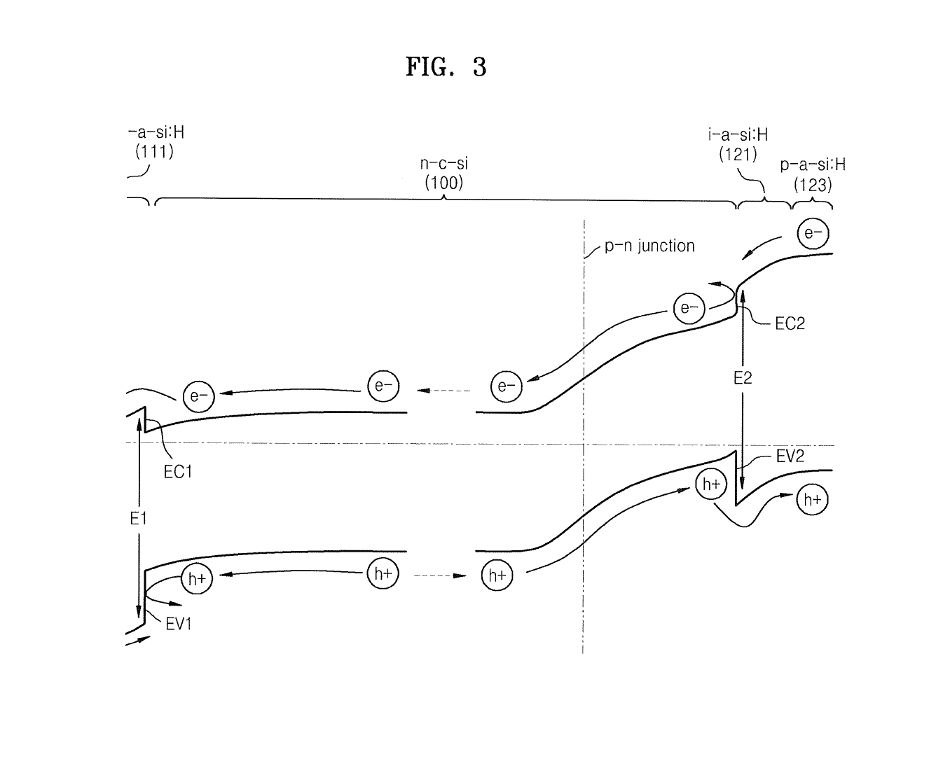

In the exemplary embodiment of FIG. 2, the recombination loss due to the contact between the first and second semiconductor stacks 110 and 120 may be reduced or minimized by forming the first and second intrinsic semiconductor layers 111 and 121 having band gaps that are different from each other, which will be described with reference to FIG. 3. Referring to FIG. 2, the insulation portion 150 includes first and second edge surfaces 151 and 152 formed on opposite (vertical) sides of the insulation portion 150. The first edge surface 151 of the insulation portion 150 is aligned with an edge surface 120aa of the second semiconductor stack 120. For example, the insulation portion 150 may be formed through patterning using the edge portion 120a of the second semiconductor stack 120 as an etch mask. As a result, the first edge surface 151 of the insulation portion 150 and the edge surface 120aa of the second semiconductor stack 120 are aligned with each other. In addition, the connection portion 120c of the second semiconductor stack 120 extends in the second direction Z2 to cover the edge surfaces 111a and 113a of the first semiconductor stack 110 and the second edge surface 152 of the insulation portion 150.

The insulation portion 150 may be formed, for example, of silicon nitride film SiNx. However, the material for forming the insulation portion 150 is not specifically limited. For example, in other embodiments, the insulation portion 150 may be formed of any insulating material that electrically insulates between the edge portions 110a and 120a of the first and second semiconductor stacks 110 and 120. The insulation portion 150 may be formed, for example, as a portion of an insulating layer that serves as an etch stop film (for example, an etch mask) when texturing the second surface S2 of the semiconductor substrate 100. Accordingly, the insulation portion 150 may be formed of a material that has a resistance to a texturing etchant.

FIG. 3 is an energy band diagram for illustrating a principle of reducing recombination loss caused by contact between the first and second semiconductor stacks 110 and 120. The notation n-a-Si:H shown in the upper left side of the drawing indicates the first conductive semiconductor layer 113 doped with an n-type dopant while the notation i-a-Si:H indicates the first intrinsic semiconductor layer 111. The first intrinsic semiconductor layer 111 and the first conductive semiconductor layer 113 form a base for collecting major carriers (for example, electrons). Moving to the right in FIG. 3, the notation n-c-Si indicates the n-type crystalline semiconductor substrate 100. In addition, the notation p-a-Si:H shown in the upper right side of the drawing indicates the second conductive semiconductor layer 123 doped with a p-type dopant, while the notation i-a-Si:H indicates the second intrinsic semiconductor layer 121. The second intrinsic semiconductor layer 121 and the second conductive semiconductor layer 123 form an emitter for collecting minor carriers (for example, holes).

Carriers, that is, electrons and holes, are optically generated in the semiconductor substrate 100 and respectively collected in the first and second semiconductor stacks 110 and 120 by charge separation caused by an internal electric field formed by a p-n junction. Band offsets EC1, EV1, EC2, and EV2 are formed at interfaces between the semiconductor substrate 100, and the first intrinsic semiconductor layer 111 and the second intrinsic semiconductor layer 121 according to the band gap difference. In FIG. 3, the EC1 and EV1 respectively indicate a conduction band offset and a valence band offset formed on a band edge of the first intrinsic semiconductor layer 111, while EC2 and EV2 respectively indicate a conduction band offset and a valence band offset formed on a band edge of the second intrinsic semiconductor layer 121.

The movement of the minor carriers (for example, holes) to the first intrinsic semiconductor layer 111 is blocked by a high potential barrier of the valence band offset EV1 formed on the band edge of the first intrinsic semiconductor layer 111. Likewise, the movement of the major carriers (for example, electrons) to the second intrinsic semiconductor layer 121 is blocked by a high potential barrier of the conduction band offset EC2 formed on a band edge of the second intrinsic semiconductor layer 121. Accordingly, the recombination loss of the optically generated carriers due to being diffused in a direction opposite to an internal electric field may be repressed by the band offsets EV1 and EC2 of the first intrinsic semiconductor layer 111 and the second intrinsic semiconductor layer 121.

In an exemplary embodiment, the first intrinsic semiconductor layer 111 and the second intrinsic semiconductor layer 121 are formed to have band gaps E1 and E2 that are different from each other (for example, by controlling a dopant, doping levels, etc.) In particular, the second intrinsic semiconductor layer 121 has a band gap E2 narrower than the band gap E1 of the first intrinsic semiconductor layer 111. For example, the second intrinsic semiconductor layer 121 is formed to have a band gap of 1.76 eV or less, while the first intrinsic semiconductor layer 111 is formed to have a band gap of 1.76 eV or more.

When the second intrinsic semiconductor layer 121 is formed to have a relatively narrow band gap E2, the valence band offset EV2 of the second intrinsic semiconductor layer 121 is reduced and the minor carriers (for example, holes) may readily move to the second intrinsic semiconductor layer 121. Further, when the first intrinsic semiconductor layer 111 is formed to have a relatively wide band gap E1, the valence band offset EV1 of the first intrinsic semiconductor layer 111 is increased and the recombination loss of the minor carriers (for example, holes) due to being diffused into the first intrinsic semiconductor layer 111 may be repressed.

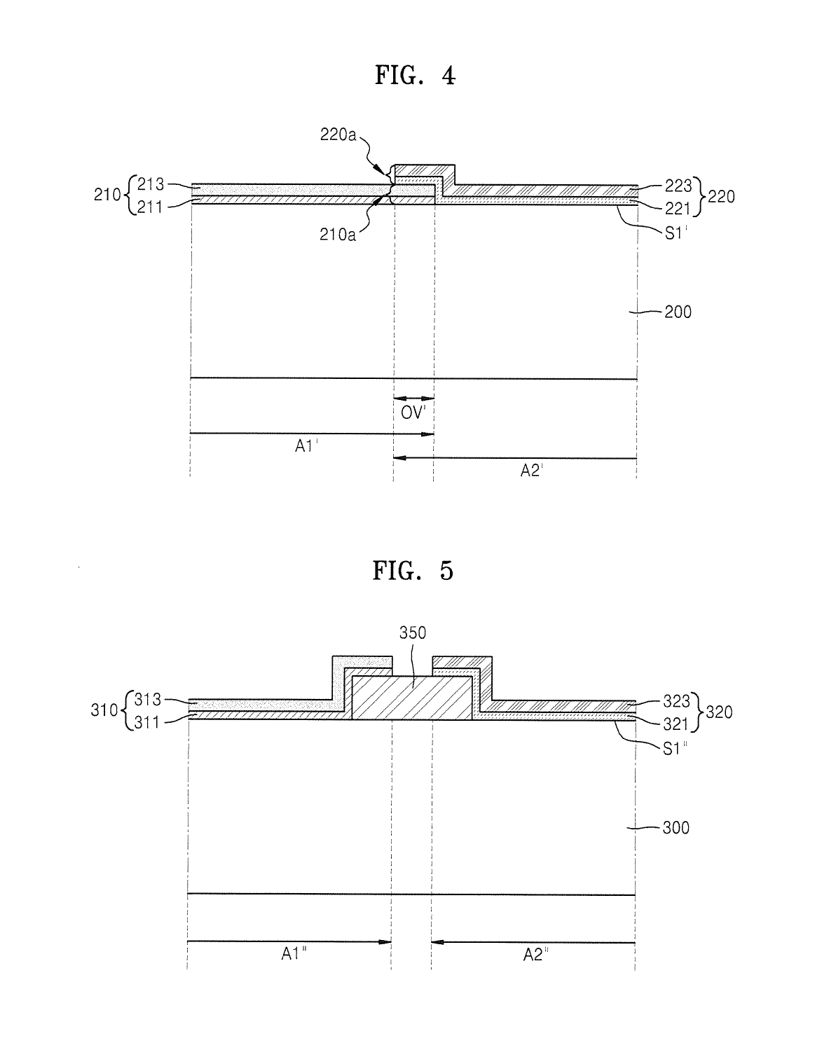

FIG. 4 is a cross-sectional view of a photoelectric device according to a comparative example 1 to compare with an embodiment of the present invention. Referring to FIG. 4, first and second semiconductor stacks 210 and 220 having conductivities opposite to each other are formed on a first surface S1′ of a semiconductor substrate 200. The first and second semiconductor stacks 210 and 220 are formed in first and second semiconductor regions A1′ and A2′ of the semiconductor substrate 200, and respectively include a first intrinsic semiconductor layer 211 and a first conductive semiconductor layer 213, and a second intrinsic semiconductor layer 221 and a second conductive semiconductor layer 223.

Edge portions 210a and 220a of the first and second semiconductor stacks 210 and 220 form an overlapping region OV′ where the first and second semiconductor stacks 210 and 220 overlap each other. The edge portions 210a and 220a of the first and second semiconductor stacks 210 and 220 contact each other along a width of the overlapping region OV′. Since the edge portions 210a and 220a of the first and second semiconductor stacks 210 and 220 form a relatively long surface contact with each other, during charge separation of carriers optically generated in the semiconductor substrate 200 to the first and second semiconductor stacks 210 and 220, carrier recombination occurs through the contact between the first and second semiconductor stacks 210 and 220. Thus, due to current leakage and recombination loss, an output characteristic is reduced.

In the exemplary photoelectric device of FIG. 2, the edge portions 110a and 120a of the first and second semiconductor stacks 110 and 120 do not contact each other, but are instead separated from each other by the insulation portion 150. Therefore, when the photoelectric device of FIG. 4 is compared with the photoelectric device of FIG. 2, the carrier recombination loss may be reduced. In the exemplary embodiment of FIG. 2, the first intrinsic semiconductor layer 111 and the second intrinsic semiconductor layer 121 are formed to contact each other. However, a contact area through the first intrinsic semiconductor layer 111 having an angstrom scale is very small, and thus, the recombination loss due to the contact therebetween may be reduced. On the other hand, in the comparative example 1, the contact width (corresponding to the width of the overlapping region OV′) between the first and second semiconductor stacks 210 and 220 is formed to be 10 μm or more (because of a process margin during fabrication). When this process margin is not followed, the semiconductor substrate 200 may be exposed between the first and second semiconductor stacks 210 and 220. This, in turn, can lead to recombination loss due to a surface defect of the semiconductor substrate 200.

FIG. 5 is a cross-sectional view of a photoelectric device according to a comparative example 2 to compare with an embodiment of the present invention. Referring to FIG. 5, first and second semiconductor stacks 310 and 320 having conductivities that are opposite to each other are formed on a first surface S1″ of a semiconductor substrate 300. The first and second semiconductor stacks 310 and 320 are formed in first and second semiconductor regions A1″ and A2″ of the semiconductor substrate 300, and respectively include a first intrinsic semiconductor layer 311 and a first conductive semiconductor layer 313, and a second intrinsic semiconductor layer 321 and a second conductive semiconductor layer 323.

A gap insulation film 350 is formed between the first and second semiconductor stacks 310 and 320 to insulate between the first and second semiconductor stacks 310 and 320 and to passivate the semiconductor substrate 300 exposed between the first and second semiconductor stacks 310 and 320. The photoelectric device according to the comparative example 2 may be formed such that, after forming a pattern of the gap insulation film 350, the first and second semiconductor stacks 310 and 320 are respectively stacked and patterned. That is, the photoelectric device according to the comparative example 2 is formed through a series of processes such as the forming of the gap insulation film 350, the patterning of the gap insulation film 350, the stacking of the first semiconductor stack 310, the patterning of the first semiconductor stack 310, the stacking of the second semiconductor stack 320, and the patterning of the second semiconductor stack 320.

However, in the process of forming the photoelectric device according to the exemplary embodiment of FIG. 2, an additional gap insulation film for insulating the first semiconductor stack 110 from the second semiconductor stack 120 is unnecessary. Accordingly, the forming of the gap insulation film and the patterning of the gap insulation film are removed, thereby reducing the number of processes. That is, the manufacturing process may be simplified, and thus, manufacturing costs may be reduced.

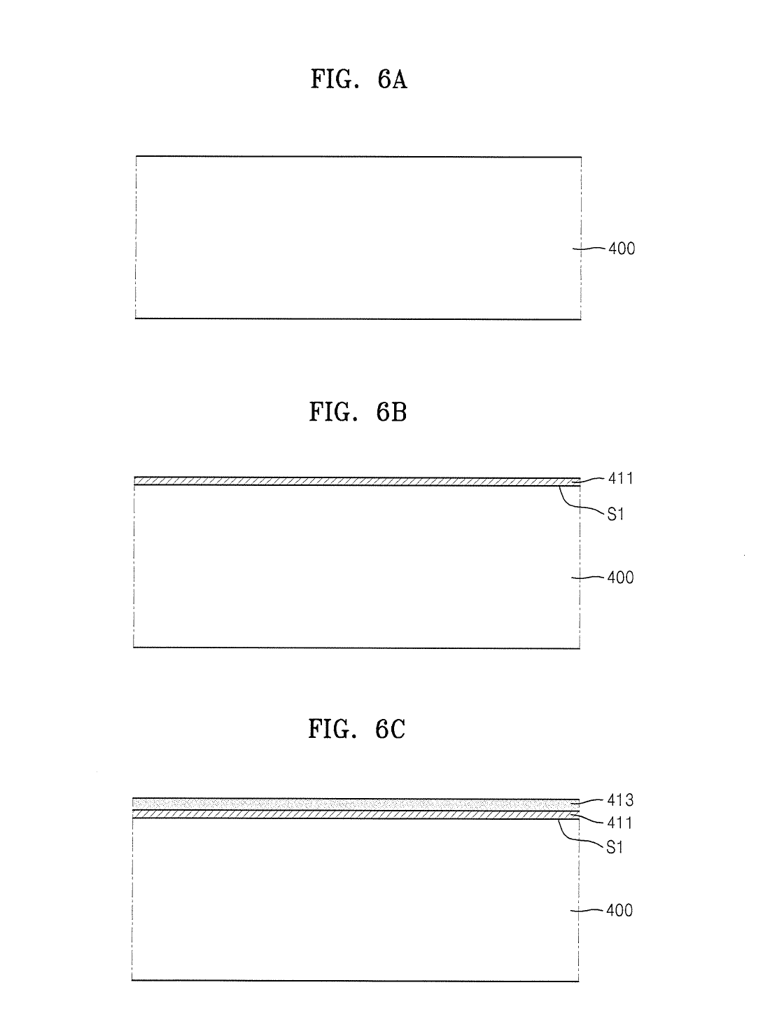

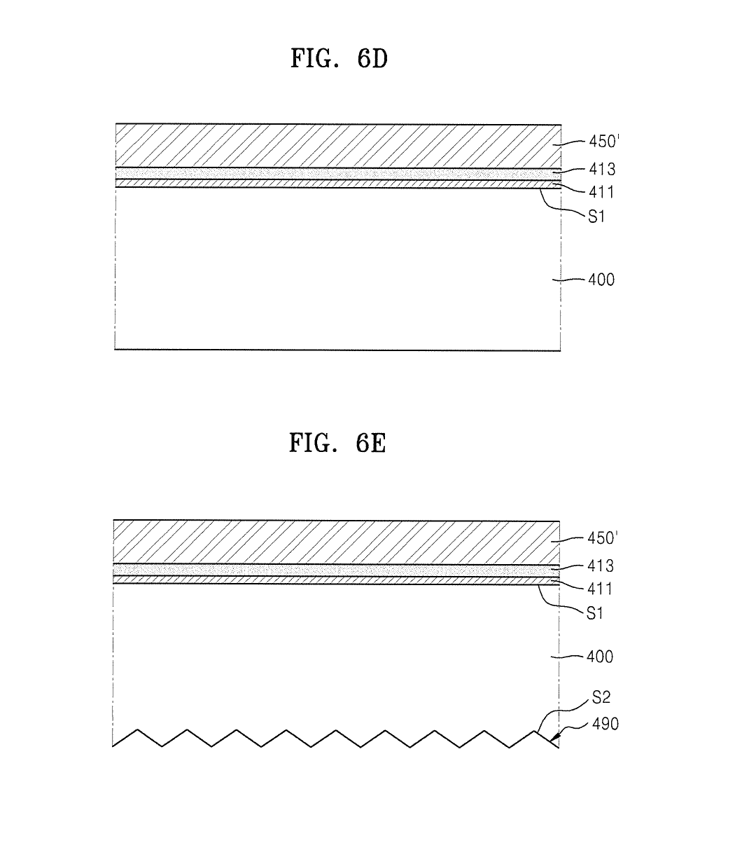

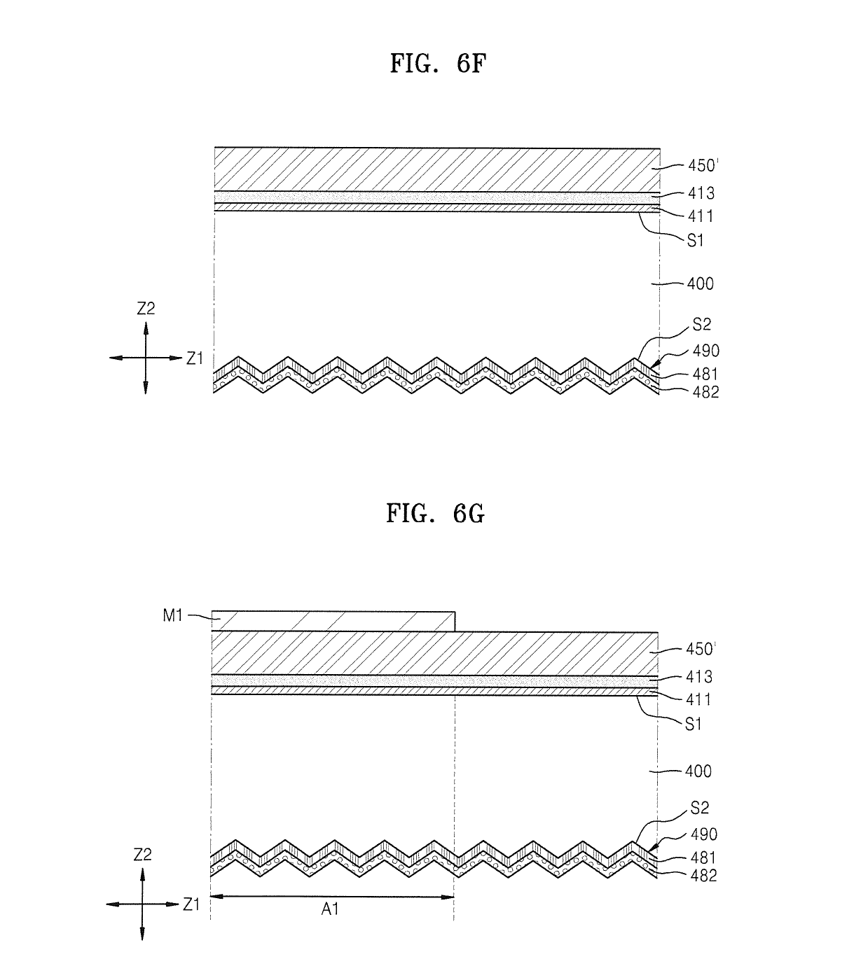

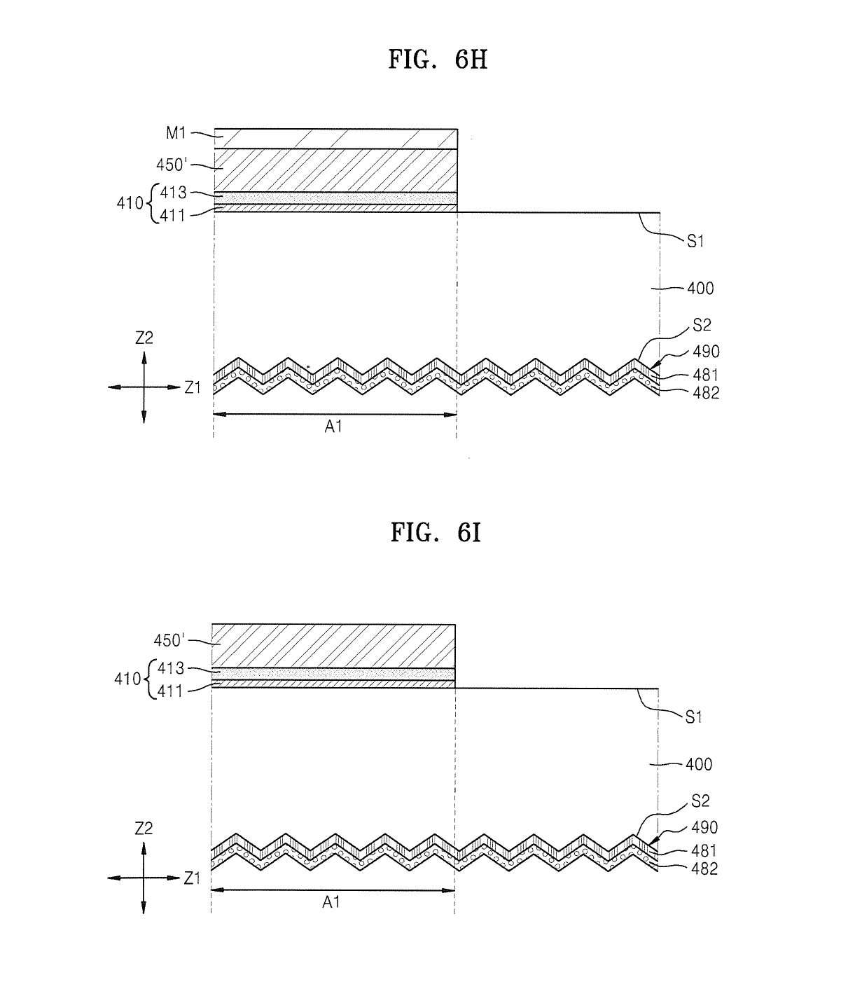

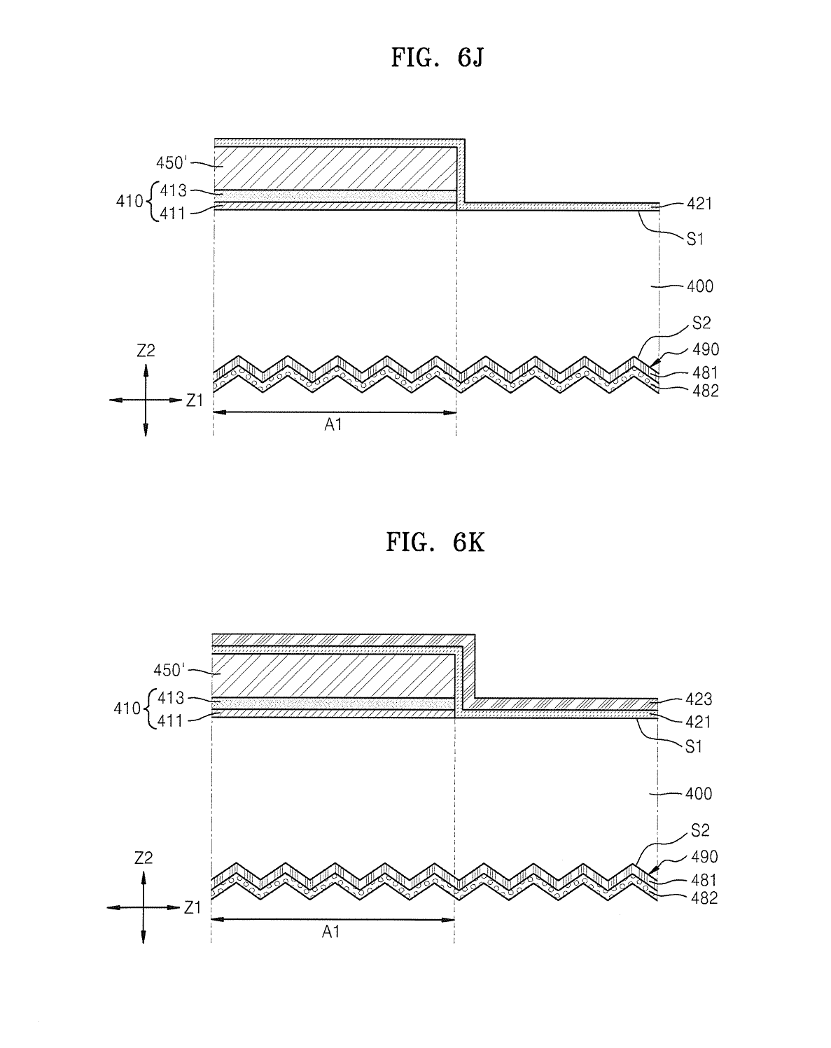

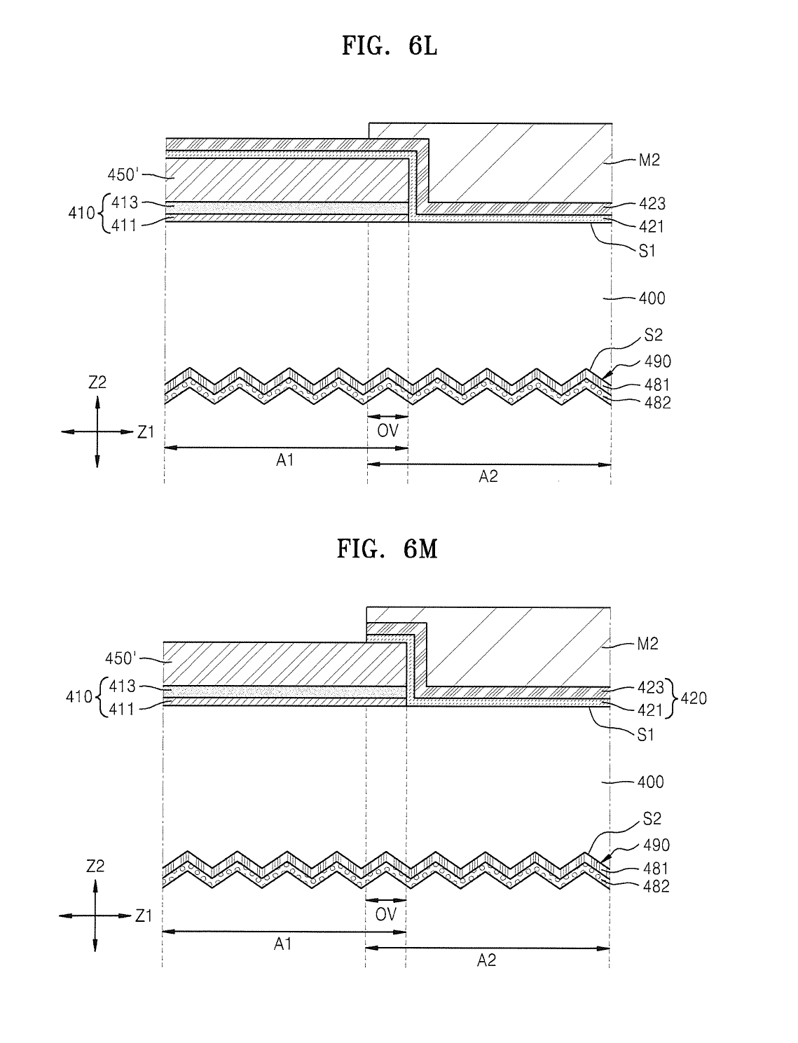

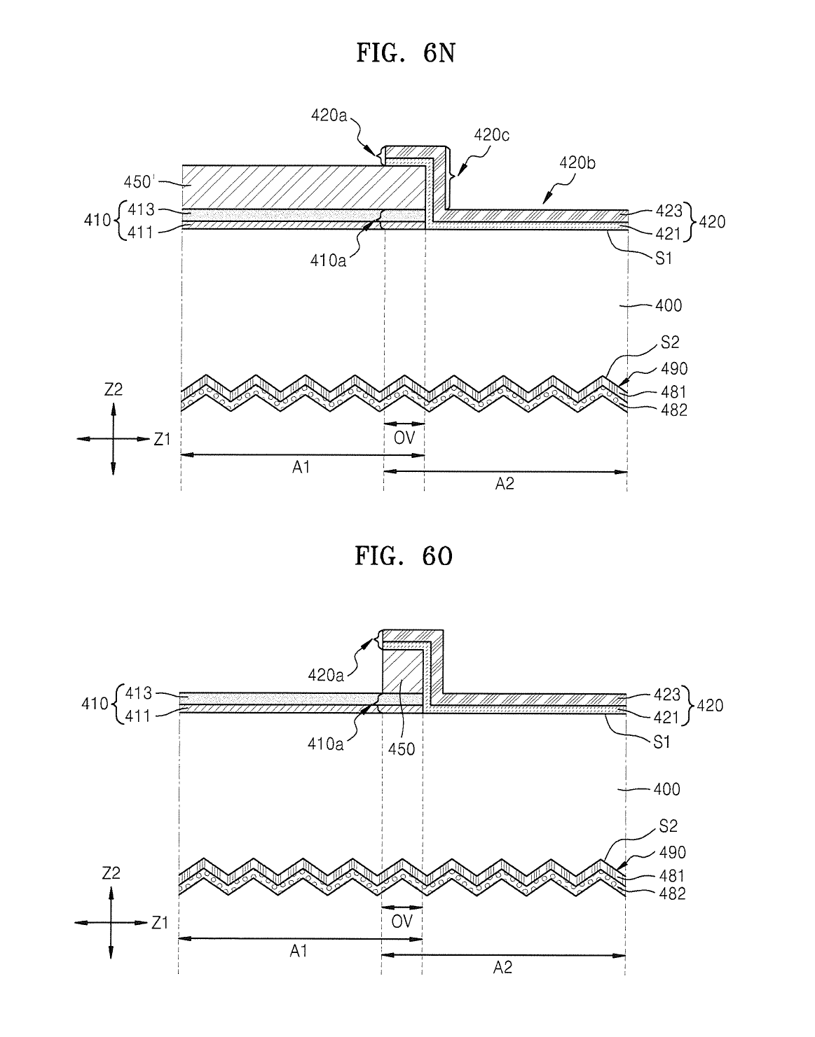

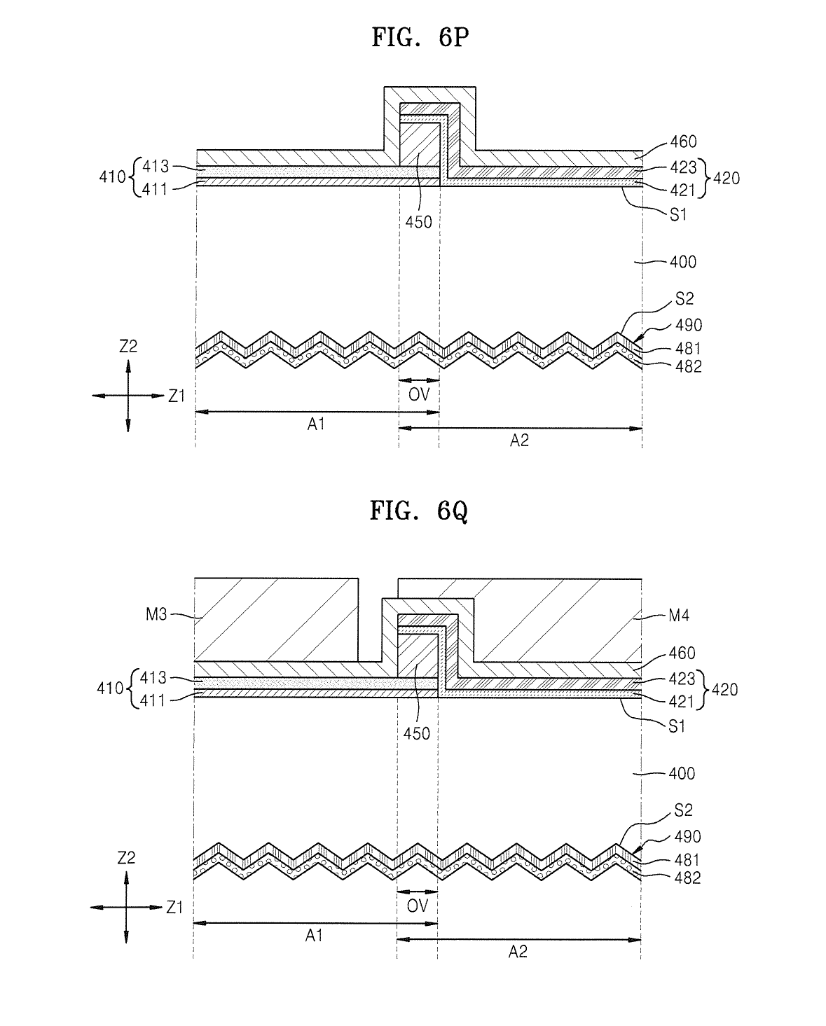

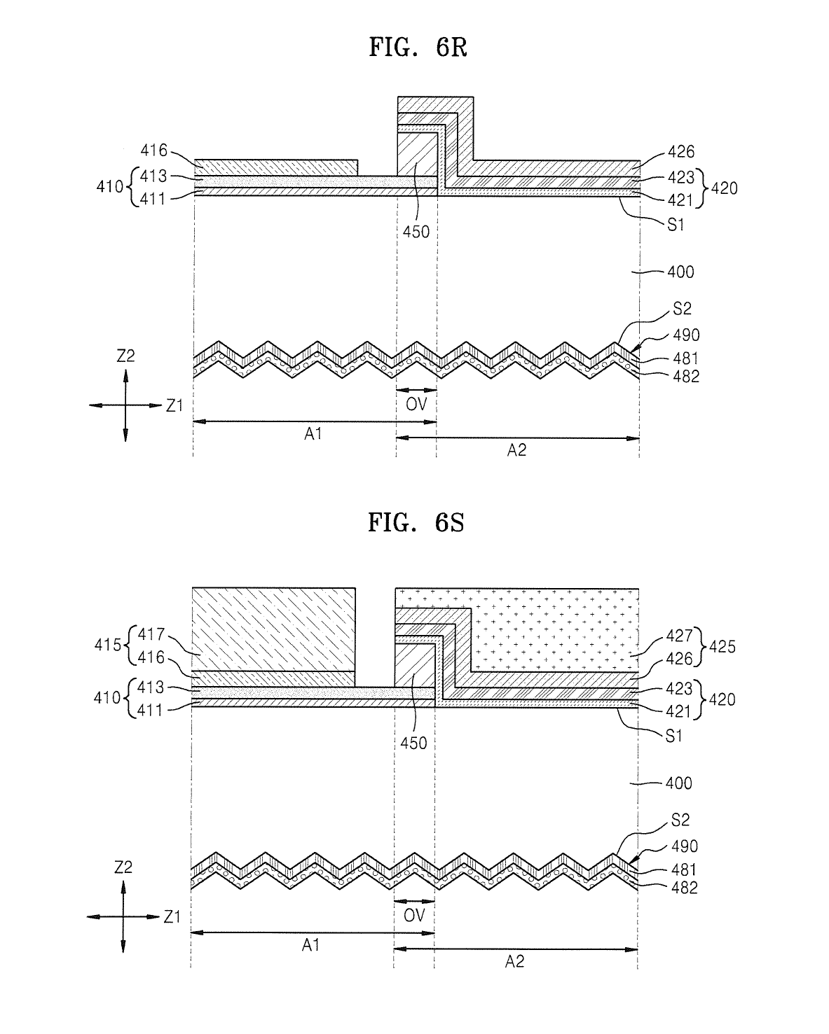

FIGS. 6A through 6S are cross-sectional views showing a method of manufacturing a photoelectric device according to an embodiment of the present invention.

Referring to FIG. 6A, a semiconductor substrate 400 is prepared. For example, the semiconductor substrate 400 may be formed of n-type crystalline silicon. A washing process for removing physical and chemical impurities adhered to a surface of the semiconductor substrate 400 may be performed by applying acids or alkalis.

Next, as shown in FIG. 6B, a first intrinsic semiconductor layer 411 is formed on a first surface S1 of the semiconductor substrate 400. For example, the first intrinsic semiconductor layer 411 may be formed through a chemical vapor deposition (CVD) method by using SiH₄ (which is a silicon-containing gas), or may be formed of amorphous silicon or hydrogenated amorphous silicon. In addition, the first intrinsic semiconductor layer 411 may be formed to have a band gap of greater than 1.76 eV. For this purpose, an additive or a small amount of dopant may be added.

Next, as depicted in FIG. 6C, a first conductive semiconductor layer 413 is formed on the first intrinsic semiconductor layer 411. For example, the first conductive semiconductor layer 413 may be doped with an n-type dopant that has the same conductivity as that of the semiconductor substrate 400. Further, the first conductive semiconductor layer 413 may be formed through a CVD method by using a doping gas (for example, PH₃) together with SiH4, or may be formed of amorphous silicon or hydrogenated amorphous silicon.

Next, as depicted in FIG. 6D, an insulating layer 450′ is formed on the first conductive semiconductor layer 413. The insulating layer 450′ may function as an etch mask when texturing, that is, forming a corrugated pattern on the surface of the semiconductor substrate 400, and therefore may be formed of a material having resistance to a texturing etchant. In addition, as described below, through patterning of the insulating layer 450′, a remaining portion of the insulating layer 450′ may form an insulation portion that separates and insulates an edge portion 410a of the first semiconductor stack 410 from an edge portion 420a of the second semiconductor stack 420. The insulating layer 450′ may be formed, for example, of a silicon nitride film SiNx by using a CVD method.

Next, as depicted in FIG. 6E, texturing with respect to a second surface S2 is performed. An etching process with respect to the second surface S2 is performed by using the insulating layer 450′ formed on the first surface S1 of the semiconductor substrate 400 as an etch mask. For example, a texture structure 490 having a corrugated pattern on the second surface S2 of the semiconductor substrate 400 is formed by performing anisotropic etching with respect to the semiconductor substrate 400 by applying an alkali solution such as KOH or HaOH.

Next, as depicted in FIG. 6F, a passivation film 481 is formed on the second surface S2 of the semiconductor substrate 400 on which the texture structure 490 is formed. The passivation film 481 may increase carrier collection efficiency by reducing or preventing the recombination of the generated carriers on the semiconductor substrate 400. The passivation film 481 may be doped, for example, to be the same conductivity as the semiconductor substrate 400. For example, the passivation film 481 may be formed as a highly doped n+ layer on the second surface S2 of the semiconductor substrate 400, and may form a front surface field (FSF) for reducing the surface recombination loss. The passivation film 481 may be formed of a silicon oxide film SiOx or a silicon nitride film SiNx by using a CVD method by applying a SiH₄ gas that includes silicon.

As further depicted in FIG. 6F, a reflection prevention film 482 is formed on the passivation film 481. The reflection prevention film 482 may be formed, for example, of a silicon oxide film or a silicon nitride film. For example, the reflection prevention film 482 may be formed of a monolayer of a silicon oxide film or a silicon nitride film, or a composite layer of a silicon oxide film and a silicon nitride film having refractive indexes different from each other. In the exemplary embodiment of FIG. 6F, the passivation film 481 and the reflection prevention film 482 are formed as separated layer structures. However, in another embodiment, the passivation film 481 and the reflection prevention film 482 may be formed as one layer structure.

Next, as depicted in FIGS. 6G through 6I, after forming an etch stop film (for example, an etch mask) M1 on a portion of the insulating layer 450′, an etching process is performed with respect to the insulating layer 450′, the first conductive semiconductor layer 413, and the first intrinsic semiconductor layer 411. That is, portions of the insulating layer 450′, the first conductive semiconductor layer 413, and the first intrinsic semiconductor layer 411 are removed except the insulating layer 450′, the first conductive semiconductor layer 413, and the first intrinsic semiconductor layer 411 formed in a first semiconductor region A1. A first semiconductor stack 410 is formed by patterning the first conductive semiconductor layer 413 and the first intrinsic semiconductor layer 411.

More specifically, after applying an etch mask M1 on the insulating layer 450′, exposed portions through the etch mask M1 are removed. That is, the portions of the insulating layer 450′, the first conductive semiconductor layer 413, and the first intrinsic semiconductor layer 411 are removed (except for the portions protected by the etch mask M1) by using an etchant. At this point, the etchant may be HF, H₃PO₄, etc., having an etch characteristic with respect to the insulating layer 450′. As depicted in FIG. 6I, the first semiconductor stack 410 (that includes the first intrinsic semiconductor layer 411 and the first conductive semiconductor layer 413, which are stacked in the first semiconductor region A1) is formed. Afterwards, the etch mask M1 is removed.

Next, as depicted in FIG. 6J, a second intrinsic semiconductor layer 421 is formed on the first surface S1 of the semiconductor substrate 400. The second intrinsic semiconductor layer 421 may be formed on the entire first surface S1 of the semiconductor substrate 400. The second intrinsic semiconductor layer 421 may be formed, for example, of amorphous silicon or hydrogenated amorphous silicon through a CVD method by applying a SiH₄ gas that includes silicon. In addition, the second intrinsic semiconductor layer 421 may be formed to have a band gap narrower than that of the first intrinsic semiconductor layer 411, for example, less than 1.76 eV. For this purpose, an additive or a small amount of dopant may be added.

Next, as depicted in FIG. 6K, a second conductive semiconductor layer 423 is formed on the second intrinsic semiconductor layer 421. The second conductive semiconductor layer 423 may be doped, for example, with a p-type dopant, which is opposite in conductivity to that of the semiconductor substrate 400. The second conductive semiconductor layer 423 may be formed, for example, of amorphous silicon or hydrogenated amorphous silicon by using a CVD method using a doping gas (for example, B₂H₆ gas) as a source gas.

As depicted in FIGS. 6L through 6N, after forming an etch mask M2 on a region of the second conductive semiconductor layer 423, etching with respect to the second conductive semiconductor layer 423 and the second intrinsic semiconductor layer 421 is performed. That is, portions of the second conductive semiconductor layer 423 and the second intrinsic semiconductor layer 421 that are not covered by the etch mask M2 are removed. A second semiconductor stack 420 is formed by patterning the second conductive semiconductor layer 423 and the second intrinsic semiconductor layer 421.

More specifically, the etch mask M2 is formed on the second conductive semiconductor layer 423, and portions exposed through the etch mask M2 are removed. That is, the portions of the second conductive semiconductor layer 423 and the second intrinsic semiconductor layer 421 that are not protected by the etch mask M2 are removed by applying an etchant. For example, the etchant may be one selected from the group consisting of HNO₃, HF, CH₃COOH, DI water, and a mixture of these materials.

When the etching is completed, as depicted in FIG. 6N, the second semiconductor stack 420 (that includes the second intrinsic semiconductor layer 421 and the second conductive semiconductor layer 423, which are stacked in the second semiconductor region A2) is formed, and the etch mask M2 is removed. The second semiconductor stack 420 includes a main body portion 420b that extends in a first direction Z1 parallel to the semiconductor substrate 400, an edge portion 420a supported by the insulating layer 450′ at a higher location than the main body portion 420b, and a connection portion 420c that extends in a second direction Z2 to connect the main body portion 420b and the edge portion 420a.

As depicted in FIG. 6O, an insulating portion 450 is formed by patterning the insulating layer 450′ formed in the first semiconductor region A1. That is, the insulating portion 450 optionally formed in the overlapping region OV is formed by removing the insulating layer 450′ except for the insulating layer 450′ that is covered by the edge portion 420a of the second semiconductor stack 420 by performing an etch process with respect to the insulating layer 450′ using a portion of the second semiconductor stack 420 as an etch mask. The insulating portion 450 is between the edge portions 410a and 420a of the first and second semiconductor stacks 410 and 420 to electrically insulate therebetween. For example, except for the portion of the insulating layer 450′ that is covered by the second semiconductor stack 420, the insulating layer 450′ may be removed by using an etchant that exhibits different characteristics with respect to the insulating layer 450′ and the second semiconductor stack 420 (more specifically, the second conductive semiconductor layer 423). The remaining insulating layer 450′ may be optionally (for example, selectively) removed.

As depicted in FIG. 6P, a transparent conductive film 460 is formed on the first and second semiconductor stacks 410 and 420. For example, the transparent conductive film 460 may be formed along the first and second semiconductor stacks 410 and 420 and an entire edge surface of the insulating portion 450. The transparent conductive film 460 may be formed, for example, of a transparent conductive oxide (TCO) such as ITO or ZnO by using a sputtering method or a CVD method.

As depicted in FIGS. 6Q and 6R, a first transparent conductive film 416 on the first conductive semiconductor layer 413 and a second transparent conductive film 426 on the second conductive semiconductor layer 423 are formed by separating the transparent conductive film 460 formed on the entire first surface S1 of the semiconductor substrate 400. That is, the transparent conductive film 460 formed on the first surface S1 of the semiconductor substrate 400 is divided so that the first and second semiconductor stacks 410 and 420 do not cause an electrical short circuit. As depicted in FIG. 6Q, an etch mask M3 and an etch mask M4 are formed on the transparent conductive film 460, and a portion of the transparent conductive film 460 exposed through the etch mask M3 and the etch mask M4 is removed. When the 0etching is completed, the etch mask M3 and the etch mask M4 are removed.

As depicted in FIG. 6S, first and second metal films 417 and 427 are formed on the first and second transparent conductive films 416 and 426. The first and second metal films 417 and 427 may be formed, for example, of a metal such as Al, Cu, or Ni. In one exemplary embodiment, the first and second metal films 417 and 427 are formed by printing a metal paste pattern on the first and second transparent conductive films 416 and 426 by using a screen printing method, followed by thermal sintering of the metal paste pattern. The first and second metal films 417 and 427 form first and second electrodes 415 and 425 together with the first and second transparent conductive films 416 and 426. The first and second electrodes 415 and 425 are respectively connected to the first and second semiconductor stacks 410 and 420 to discharge carriers to the outside.

According to embodiments of the present invention, there is provided a photoelectric device having a rear surface contact structure in which an electrode structure on a light receiving surface is removed to reduce or minimize optical loss. In addition, in a photoelectric device according to embodiments of the present invention, a manufacturing process may be simplified and recombination loss of optical carriers generated in a semiconductor substrate may be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims, and equivalents thereof.

What is claimed is:

1. A photoelectric device comprising:
a semiconductor substrate;
a first semiconductor stack on a first surface of the semiconductor substrate and having a first conductivity; and
a second semiconductor stack on the first surface of the semiconductor substrate and having a second conductivity opposite to the first conductivity,
wherein edge portions of the first and second semiconductor stacks face each other with an insulating portion therebetween.

2. The photoelectric device of claim 1, wherein the first semiconductor stack constitutes a base for collecting major carriers and the second semiconductor stack constitutes an emitter for collecting minor carriers.

3. The photoelectric device of claim 2, wherein the edge portion of the first semiconductor stack, the insulating portion, and the edge portion of the second semiconductor stack are stacked sequentially from the semiconductor substrate.

4. The photoelectric device of claim 1, wherein the edge portions of the first and second semiconductor stacks are vertically separated from each other by a first height.

5. The photoelectric device of claim 1, wherein
the edge portion of the second semiconductor stack is supported on the insulation portion, and
an edge surface of the second semiconductor stack and an edge surface of the insulating portion are aligned with each other.

6. The photoelectric device of claim 1, wherein the edge portion of the first semiconductor stack extends on the semiconductor substrate in a first direction parallel to the semiconductor substrate.

7. The photoelectric device of claim 1, wherein the edge portion of the second semiconductor stack is vertically separated by a second height from a main body portion of the second semiconductor stack that extends in a first direction parallel to the semiconductor substrate.

8. The photoelectric device of claim 7, wherein the second semiconductor stack further comprises a connection portion that extends in a second direction different from the first direction to connect the main body portion and the edge portion.

9. The photoelectric device of claim 8, wherein the connection portion of the second semiconductor stack extends in the second direction to cover an edge surface of the first semiconductor stack and the edge surface of the insulating portion.

10. The photoelectric device of claim 9, wherein the connection portion of the second semiconductor stack contacts the edge surface of the first semiconductor stack.

11. The photoelectric device of claim 10, wherein
the first semiconductor stack comprises a first intrinsic semiconductor layer and a first conductive semiconductor layer that extend in the first direction on the semiconductor substrate, and
the connection portion of the second semiconductor stack comprises a second intrinsic semiconductor layer and a second conductive semiconductor layer that extend parallel to each other in the second direction.

12. The photoelectric device of claim 11, wherein the second intrinsic semiconductor layer contacts an edge surface of the first intrinsic semiconductor layer.

13. The photoelectric device of claim 12, wherein
the second intrinsic semiconductor layer contacts the first intrinsic semiconductor layer along a thickness direction of the first intrinsic semiconductor layer, and
the first intrinsic semiconductor layer has a thickness smaller than that of the first conductive semiconductor layer.

14. The photoelectric device of claim 11, wherein the second intrinsic semiconductor layer contacts an edge surface of the first conductive semiconductor layer.

15. The photoelectric device of claim 11, wherein the second intrinsic semiconductor layer constitutes an emitter having a band gap narrower than that of the first intrinsic semiconductor layer constituting a base.

16. The photoelectric device of claim 1, wherein the insulating portion comprises a silicon nitride film.

17. The photoelectric device of claim 1, wherein
the first semiconductor stack comprises a first intrinsic semiconductor layer and a first conductive semiconductor layer stacked on the semiconductor substrate, and
the second semiconductor stack comprises a second intrinsic semiconductor layer and a second conductive semiconductor layer.

18. The photoelectric device of claim 17, further comprising first and second transparent conductive films respectively on the first and second conductive semiconductor layers.

19. The photoelectric device of claim 18, further comprising first and second metal films respectively on the first and second transparent conductive films.
